(19) United States
(12) Patent Application Publication
(10) Pub. No.: US 2018/0258536 A1
(43) Pub. Date: Sep. 13, 2018

(54) APPARATUS FOR PROCESSING A SURFACE OF SUBSTRATE AND METHOD OPERATING THE APPARATUS

(71) Applicant: BENEQ OY, Espoo (FI)

(72) Inventors: Leif Keto, Espoo (FI); Pekka Soininen, Espoo (FI); Mikko Söderlund, Espoo (FI)

(73) Assignee: BENEQ OY, Espoo (FI)

(21) Appl. No.: 15/751,567

(22) PCT Filed: Aug. 30, 2016
(86) PCT No.: PCT/FI2016/050593

§ 371 Date: Feb. 9, 2018

(30) Foreign Application Priority Data
Sep. 2, 2015 (FI) 20155630

(51) Int. Cl. C23C 16/54; C23C 16/44; C23C 16/455; C23C 16/50; H01J 37/32

(52) U.S. Cl. CPC C23C 16/545; C23C 16/4401; C23C 16/45536; H01J 37/3277; C23C 16/45557; C23C 16/50; C23C 16/45544

(57) ABSTRACT

The invention relates to an apparatus for processing a surface of a substrate by atomic layer deposition and to a method for operating the apparatus. The apparatus includes a deposition chamber and one or more lead-through connections provided between one or more side chambers and the deposition chamber. The one or more lead through connections includes one or more lead-through chambers and a secondary pressure device operatively connected to the one or more lead-through chambers.

### FIELD OF INVENTION

The present invention relates to an apparatus for processing a surface of a substrate, and particularly to an apparatus according to the preamble of claim 1. The present invention further relates to a method for operating a substrate processing apparatus, and more particularly to a method according to the preamble of claim 10.

### BACKGROUND OF THE INVENTION

In ALD applications, a surface of a substrate is typically subjected successively to at least two gaseous precursors. The gaseous precursors effectively react with the substrate surface, resulting in deposition of a single atomic layer. The precursor stages are typically followed or separated by a purge stage that eliminates the excess precursor from the surface of the substrate prior to the separate introduction of the other precursor. Therefore an ALD process requires alternating in sequence the flux of precursors to the surface of the substrate. This repeated sequence of alternating surface reactions and purge stages between is a typical ALD deposition cycle. Atomic layer deposition is usually carried out in a deposition chamber which is sealed from the surrounding atmosphere in order to prevent precursor gases from spreading to surroundings and also for preventing contamination from entering the deposition chamber. The atomic layer deposition may be carried out in the deposition chamber by successively supplying at least first and second precursors into the deposition chamber according to the principles of atomic layer deposition. As the subjecting of the surface is done successively, the separation of the precursors is temporal.

Alternatively, a nozzle head may be used for subjecting the subjecting a surface of a substrate to successive surface reactions of at least a first precursor and a second precursor. When nozzle head is used, the whole deposition chamber is not filled with precursors, but the precursors are supplied locally on the surface of the substrate. In this case, the precursors are separated spatially as they subject the surface simultaneously at different locations of the substrate.

Atomic layer deposition method is very susceptible to unwanted and harmful contamination. Contamination and soiling of the atomic layer deposition apparatus and especially the deposition chamber of the apparatus compromises the atomic layer deposition process causing deterioration of the quality of the formed coating. Many ALD precursors react with gasses present in the ambient air atmosphere, e.g. with water vapour and create unwanted residue growth. Thus, if air is able to leak into the inside of the ALD deposition chamber, unwanted contamination easily occurs. Furthermore, due to contamination and soiling the deposition chamber has to be cleaned. Cleaning the deposition chamber means downtime for the apparatus and process, and thus the efficiency of the process decreases. For preventing soiling and contamination of the deposition chamber entry of the contaminants and excess materials into the deposition chamber has to be prevented or minimized.

The deposition chamber comprises one or more lead-through ports provided to the walls of the deposition chamber for transporting substrate to be coated into and out of the deposition chamber. These lead-through ports are main way for the contaminants and excess materials, such as moisture, to enter the deposition chamber.

In prior art apparatuses the contamination and soiling of the deposition chamber tried to be prevented or minimized by sealing as tight as possible the lead-through ports through which the substrate is transported into and from the deposition chamber. However, sealing does not prevent all contaminants and excess materials from entering the deposition chamber and sealing also makes the apparatus more complex. Another prior art solution for minimizing the contamination and soiling is to provide a separate a vacuum chamber and arranging the deposition chamber inside the vacuum chamber. Arranging the deposition chamber inside the vacuum chamber reduces the amount of contaminants and excess materials entering the deposition chamber. However, the apparatus becomes complex and the loading and unloading of substrates becomes also difficult and complex.

### BRIEF DESCRIPTION OF THE INVENTION

An object of the present invention is to provide an apparatus and a method so as to overcome or at least alleviate the prior art disadvantages. The objects of the invention are achieved by an apparatus according to the characterizing portion of claim 1. The objects of the present invention are further achieved by a method according to the characterizing portion of claim 10.

The preferred embodiments of the invention are disclosed in the dependent claims.

The invention is based on the idea of operating the deposition chamber of the apparatus at higher pressure than lead-through connections provided to the deposition chamber. This means that the pressure inside the deposition chamber is kept at higher level than outside of the deposition chamber at the lead-through connections during the operation of the apparatus. The lead-through connections comprise a first lead-through port provided to the deposition chamber. The first lead-through port provides access between the inside and outside of the deposition chamber at the lead-through connection. According to the present invention the pressure inside the deposition chamber is provided at higher level than outside the deposition chamber, meaning outer side of the first lead-through port provided to the deposition chamber. Thus there is pressure difference over first lead through port.

In the present invention the above mentioned is realized with an apparatus for processing a surface of a substrate. The apparatus comprises a deposition chamber inside which the surface of the substrate is processed by subjecting the surface of the substrate to successive surface reactions of at least a first precursor and a second precursor according to principles of atomic layer deposition. The deposition chamber comprises deposition chamber walls. The apparatus comprises one or more one or more side chambers connected to the deposition chamber. The side chamber may be a loading chamber, process chamber or the like chamber from which the substrate to be coated is transported into deposition chamber and/or to which the substrate is transported from the deposition chamber. The apparatus further comprises one or more lead-through connections provided between the one or more side chambers and the deposition chamber and arranged to form one or more lead-throughs from the one or more side chambers to inside the deposition chamber. Thus the side chambers are connected to the deposition chamber via the lead-through connections. In order to provide control of pressure of the deposition chamber such that the pressure inside the deposition chamber is higher than outside the deposition chamber, the one or more lead-through connections comprise one or more lead-through chambers provided between the one or more side chambers and the deposition chamber and a secondary pressure device operatively connected to the one or more lead-through chambers for controlling a second pressure inside the lead-through-chamber. The lead-through chamber and the secondary pressure device enable controlling the pressure at the lead-through connection of the deposition chamber such that the pressure immediately outside the deposition chamber may be adjusted to be lower than the pressure inside the deposition chamber at all times during operation of the apparatus. According to the present invention the method comprises operating the apparatus by controlling the second pressure inside the one or more lead through chambers during the operation of the apparatus using the secondary pressure device.

The technical effect of the present invention is that the gas flow is always outwards from the deposition chamber through the lead-through connections due to the higher pressure inside the deposition chamber than in the lead-through connection and in the lead-through chamber.

An advantage of the present invention is that the higher pressure in the deposition chamber and the gas flow outwards from the deposition chamber via the lead-through connection prevents contamination and excess materials from entering the deposition chamber. Thus the contamination of the deposition chamber may be prevented or minimized which further extends the cleaning or maintenance cycle of the deposition chamber and further enhances the efficiency of the apparatus.

### BRIEF DESCRIPTION OF THE DRAWINGS

In the following the invention will be described in greater detail by means of preferred embodiments with reference to the attached [accompanying] drawings, in which

FIG. 1 shows schematically one embodiment of an apparatus for processing substrates according to the present invention;

FIG. 2 shows schematically another embodiment of an apparatus for processing substrates according to the present invention;

FIG. 3 shows yet another embodiment of an apparatus according to the present invention.

### DETAILED DESCRIPTION OF THE INVENTION

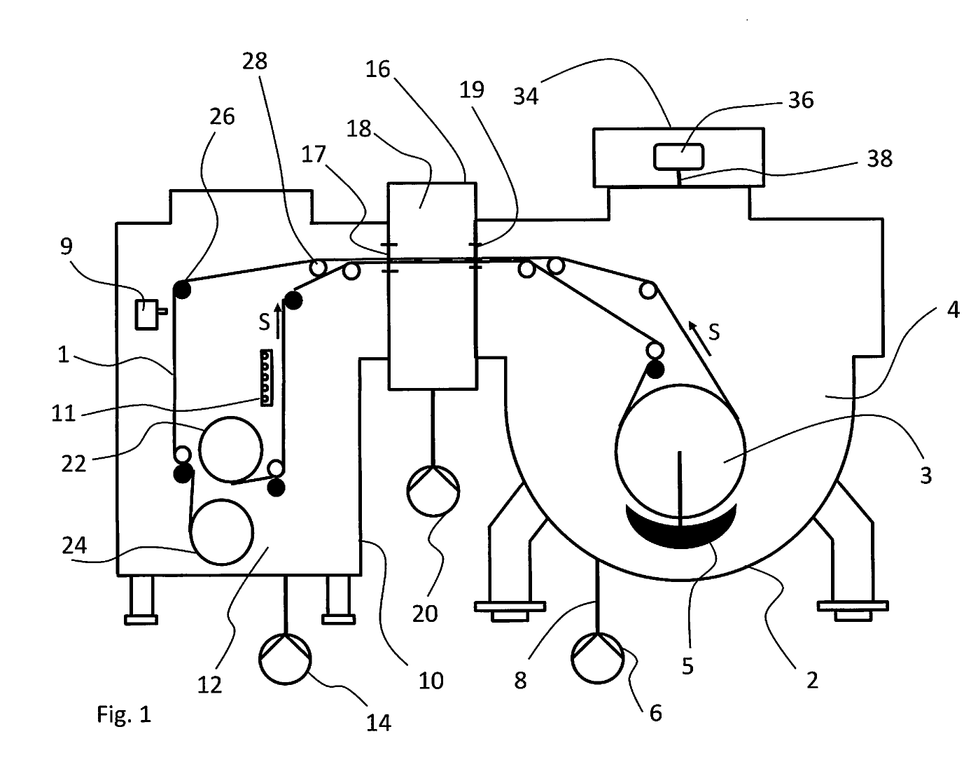

FIG. 1 is shows schematically one an embodiment of an apparatus for processing a surface of a substrate 1 according to the present invention. The apparatus comprises a deposition chamber 4 inside which the surface of the substrate 1 is processed by subjecting the surface of the substrate 1 to successive surface reactions of at least a first precursor and a second precursor according to principles of atomic layer deposition. The deposition chamber 4 comprises deposition chamber walls 2 defining a reaction space inside the deposition chamber 4. The apparatus further comprises a primary pressure device 6 operatively connected to the deposition chamber 4 via pressure connection 8 for controlling the pressure inside the deposition chamber 4.

One or more one or more side chambers 12 may be connected to the deposition chamber. The side chamber 12 is connected to the deposition chamber 4 with lead-through connections 16 provided between the side chamber 12 and the deposition chamber 4. The lead through connection 16 is arranged to form a lead-throughs from the side chambers 12 to inside the deposition chamber 4.

The side chamber 12 may be any kind of chamber from which the substrate 1 is transported into the deposition chamber 4 via the lead-through connection 16, or from the deposition chamber 4 to the side chamber 12, or to and from the deposition chamber 4. Thus the lead-through connection 16 of the present invention is substrate lead-through connection though which the substrate is transported between the side chamber 12 and the deposition chamber 4.

The lead-through connections 16 comprise one or more lead-through chambers 18 provided between the side chambers 12 and the deposition chamber 4. The lead-through connection 16 further comprises one or more second lead-through ports 17 provided between the side chamber 12 and the lead-through chamber 18, as well as one or more first lead-through ports 19 provided between the lead-through chamber 18 and the deposition chamber 4. Thus the lead-through chamber 18 comprises first and second lead-through ports 17, 19 for forming a lead-through between the side chamber 12 and the deposition chamber 4 and through the lead-through chamber 18, as shown in FIG. 1.

The lead-through chamber 18 may be any kind of chamber, vessel, container or the like having walls defining an inner space and having the first and second lead-through ports 17, 19 provided to the walls.

The apparatus may also comprise two or more lead-through connections between the side chamber 12 and the deposition chamber 4. For, example there may be one lead-through connection 16 for transporting the substrate 1 to the deposition chamber 4 and another lead-through connection for transporting the substrate 1 from the deposition chamber 4.

The lead-through port 19, 17 may be an opening, a gate valve, hatch or the like. The lead-through port 19, 17 may also comprise one or more barrier gas nozzles for providing a barrier gas stream for sealing the lead-through port 19, 17.

The lead-through connection 16 further comprises a secondary pressure device 20 operatively connected to the one or more lead-through chambers 18 for controlling pressure in the lead-through-chamber 18. Therefore the pressure inside the lead-through chamber 18 may be controlled independently of the pressure of the deposition chamber 4.

The pressure device 6, 20 may be a vacuum pump, pressurizer or vacuum pressurizer or some other device enabling control and adjustment of the pressure inside a chamber.

The primary pressure device 6 of the deposition chamber 4 may arranged to provide a first pressure inside the deposition chamber 4 and the secondary pressure device 20 of the lead-through connection 16 may be arranged to provide a second pressure inside the lead-through chamber 18. According to the principle of the present invention the second pressure inside the lead-through chamber 18 is lower than the first pressure inside the deposition chamber 4 during the operation of the apparatus.

The primary pressure device 6 and the secondary pressure device 20 may be arranged independently controllable such that during operation they are adjusted independently or separately. In an alternative embodiment the primary and secondary pressure device are operatively connected such that the secondary pressure device 20 is adjusted based on the control or adjustment of the primary pressure device 6 or first pressure inside the deposition chamber 4, or such that the primary pressure device 6 is adjusted based on the control or adjustment of the secondary pressure device 20 or second pressure inside the lead-through chamber 18. In each case the first and second pressure are adjusted relative to each other such that the first pressure inside the deposition chamber 4 is higher than the second pressure inside the one or more lead-through chambers 18 during the operation of the apparatus. It should be noted that the primary pressure device may also be omitted and providing the lower pressure to the lead-through chamber 18 may be carried out only with the secondary pressure device 20.

As shown in FIG. 1, the apparatus further comprises the side chamber 12 connected to the deposition chamber 4 via the lead-through connection 16. The side chamber 12 in FIG. 1 is a process chamber. The side chamber, or process chamber, 12 is provided with a side chamber pressure device 14, or process chamber pressure device, for controlling the pressure inside of the process device 12. The process chamber pressure device 14 may be a vacuum pump, pressurizer or vacuum pressurizer or some other device enabling control and adjustment of the pressure inside a chamber. The process chamber pressure device 14 may be arranged to provide third pressure inside the process chamber 12.

The third pressure inside the process chamber 12 may be controlled during the operation of the apparatus using the process chamber pressure device 14. The adjustment may be carried out by adjusting the second and third pressure relative to each other such that the third pressure inside the process chamber 12 is higher than the second pressure inside the one or more lead-through chambers 18 during the operation of the apparatus. Alternatively, adjustment may be carried out by adjusting the second and third pressure relative to each other such that the third pressure inside the process chamber 12 is lower than the second pressure inside the one or more lead-through chambers 18 during the operation of the apparatus, or such that the third pressure inside the process chamber 12 is substantially equal to the second pressure inside the one or more lead-through chambers 18 during the operation of the apparatus. The adjustment may also be carried out by adjusting the first, second and third pressure relative to each other such that the third pressure corresponds substantially normal air pressure (NTP) surrounding the apparatus or is substantially 1 bar, the second pressure being lower that the third pressure and the first pressure being higher than the second pressure, or such that the first, second and third are vacuum pressures under 1 bar.

In the present invention the second pressure inside the one or more lead through chambers 18 is controlled during the operation of the apparatus using the secondary pressure device 20. The method may further comprise controlling the first pressure inside the deposition chamber 4 during the operation of the apparatus using the primary pressure device 6.

The first and second pressure may be controlled relative to each other such that the first pressure inside the deposition chamber 4 is higher than the second pressure inside the one or more lead-through chambers 18 during the operation of the apparatus.

The operation of the apparatus means all kinds of operation of the apparatus, and different operation modes of the apparatus. The operation of the apparatus may mean at least the following: carrying out atomic layer deposition process in the deposition chamber 4 of the apparatus, maintenance process or maintenance work of the apparatus, changing the first pressure inside the deposition chamber 4, changing the second pressure inside the lead-through chamber 18, changing the third pressure in the process chamber 12, venting the apparatus or deposition chamber and loading and unloading of substrate or segments of continuous substrate like web or film into and from the deposition chamber 4. Accordingly, adjusting the first and second pressure relative to each other during the operation of the apparatus means at least the above mentioned.

During operation the primary and secondary pressure device 6, 20 may be controlled or adjusted independently of each other such that the first pressure inside the deposition chamber 4 is higher than the second pressure inside the one or more lead-through chambers 18. Alternatively during operation the second pressure may be adjusted with the secondary pressure device 20 based on the control or adjustment of the primary pressure device 6 or first pressure inside the deposition chamber 4, the first pressure may be adjusted with the primary pressure device 6 based on the control or adjustment of the secondary pressure device 20 or second pressure inside the lead-through chamber 18.

In an embodiment in which the process chamber 12, as shown in FIG. 1, comprises and the side chamber pressure device 14 for providing the third pressure inside the process chamber 12 the third pressure may be adjusted or controlled inside the process chamber 12 during the operation of the apparatus using the side chamber pressure device 14.

During the operation of the apparatus the second and third pressure may be adjusted relative to each other such that the third pressure inside the process chamber 12 is higher than the second pressure inside the one or more lead-through chambers 18, or such that the third pressure inside the process chamber 12 is lower than the second pressure inside the one or more lead-through chambers 18. Alternatively the second and third pressure may be adjusted relative to each other such that the third pressure inside the process chamber 12 is substantially equal to the second pressure inside the one or more lead-through chambers 18 during the operation of the apparatus.

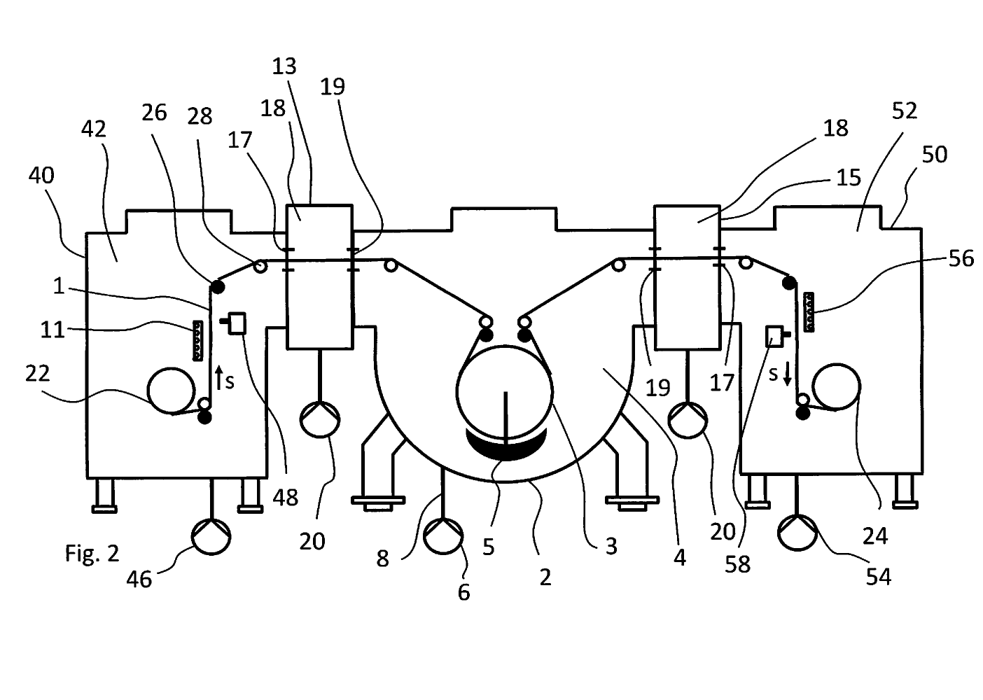

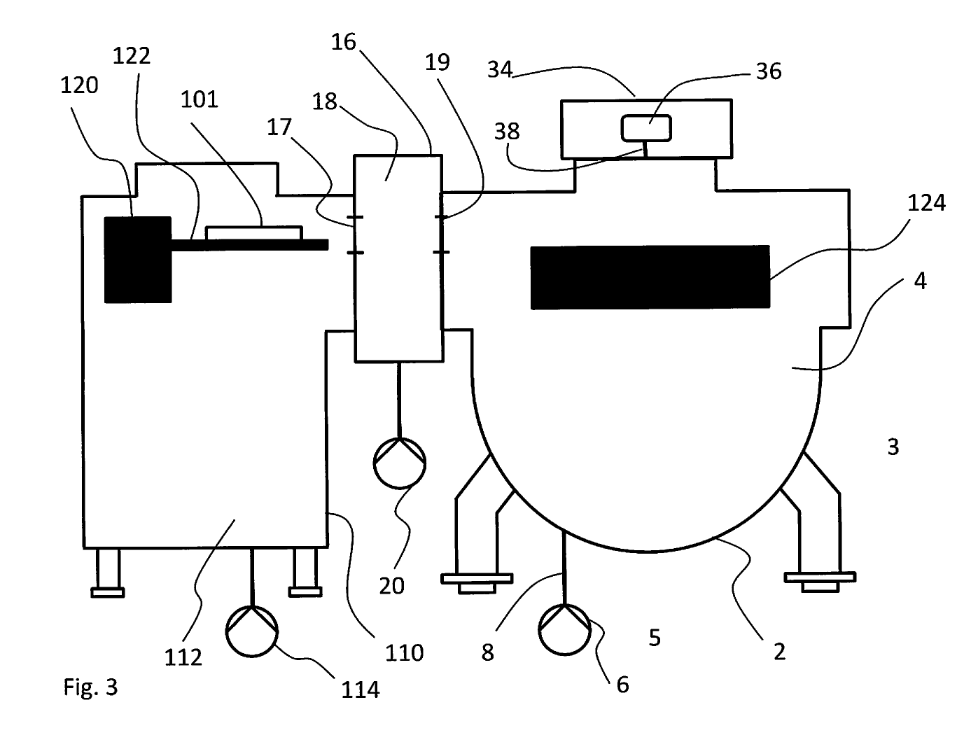

It should be noted that all of the above described in connection with the brief description and detailed description of the invention are common to all embodiments of the invention and concern the general principles of the present invention. In the following different apparatus are described in connection with FIGS. 1, 2 and 3. It should be further noted that all the above described in connection with the side chamber, or process chamber, 12 of FIG. 1, are also applicable to side chambers, or process chambers, 42, 52 and 112 of FIGS. 2 and 3, and thus the same disclosure as above is omitted.

In the embodiment of FIG. 1, the side chamber 12 is a process chamber having side chamber walls 10. The embodiment of FIG. 1 discloses a roll-to-roll apparatus in which the web-like substrate 1 continuously transported during processing the substrate. The apparatus comprises a first reel 22 from which the substrate 1 is unwound (this process is also called “supply” or reel off) and a second reel 24 to which the substrate is rewound (or reeled up or stored). The apparatus further comprises transport mechanism for transporting the substrate 1 from the first reel 22 to the second reel 24 along a transport path in the direction of arrow S in FIG. 1. The transport mechanism comprises one or more drive rolls 26, to which drive power is supplied for moving the substrate 1 along the transport path and free rolls 28 for guiding and supporting the substrate 1 along the transport path.

The side chamber 12 is connected to the deposition chamber 4 with the lead-through connection 16. The lead-through connection 16 is a substrate lead-through connection via which the substrate 1 transported between the process chamber 12 and the deposition chamber 4. The substrate 1 is transported with the transport mechanism 22, 24, 26, 28 from the process chamber 12 to the deposition chamber and back to the process chamber 12 via the lead-through connection 16. Thus the process chamber 12 is also a loading chamber and unloading chamber of the apparatus.

The process chamber 12 may comprise one or more pre-treating devices 11 for pre-treating the substrate 1 before transporting the substrate 1 to the deposition chamber 4. In the embodiment of FIG. 1, the pre-treating device is a heater for heating the substrate 1. The process chamber may also 12 comprises one or more post-treating devices 9 for post-treating the substrate 1 after transporting the substrate 1 from the deposition chamber 4. In the embodiment of FIG. 1, the post-treating device 9 is plasma processing device 9 for plasma treating the substrate 1. The plasma processing device may be arranged to provide radicals using plasma discharge.

The pre-treating devices 9 and the post-treating devices may be for example heating device, cooling device, coating device, plasma processing device, tacky roll or any kind of substrate processing device.

A tacky roll comprises at least one roller to lift the contamination from the web and transfers it to a semi-adhesive, that is, tacky, roll. This locks the contaminant down and removes it from the process, instead of letting it slip back into the production line.

The deposition chamber 4 is provided with a substrate support cylinder 3 having an outer cylinder surface along which the substrate 1 is transported. In connection with the substrate support 3 is provided a nozzle head 5 comprising a gas manifold for supplying at least a first and second precursor on the surface of the substrate 1 as the substrate is transported on the substrate support 3.

It should be noted that the nozzle head 5 and the substrate support 3 may be implemented in any form and the present invention is restricted to any specific nozzle head or substrate support.

The first and second precursors may be precursor gases which provide surface reactions according to the principles of atomic layer deposition. This means that the precursors may provide successive saturated surface reactions. The first or second precursor may also be provided as precursor radicals formed by using plasma. The plasma may be provided with plasma equipment provided to the nozzle head 5.

The apparatus further comprises other process equipments connected to the deposition chamber 4. Process equipment 34 is a gas source 36 arranged to supply process gas, such as precursor(s), purge gas, inert gas or venting gas, inside the deposition chamber 4. The lead-through connection 16 between the gas source 36 and the deposition chamber 4 is a process gas lead-through connection via which the process gas is supplied to the deposition chamber 4. The gas source 36 also comprises a gas line 38 extending from the gas source 34 through the lead-through chamber 16.

In the embodiment of FIG. 1, the gas source 36 may be arranged supply inert gas, such as nitrogen, into the deposition chamber 4 for providing an inert gas atmosphere.

In an alternative embodiment, the process equipment 34 may be a gas discharge arranged to exhaust process gas or gases from the deposition chamber 4.

FIG. 2 shows an alternative embodiment in which the apparatus comprises a first side chamber 42 or a loading chamber, a second side chamber 52 or an unloading chamber and a transport mechanism 22, 24, 26, 28, 3 arranged to transport the substrate 1 from the first side chamber 42 or the loading chamber to the deposition chamber 4 via a first substrate lead-through connection 13 and from the deposition chamber 4 to the second side chamber 52 or the unloading chamber via a second substrate lead-through connection 15. Thus the deposition chamber is provided between the first and second side chamber 42, 52. The first and second side chambers 42, 52 are connected to the deposition chamber 4 with the first and second lead-through connections 13, 15 in the same manner as the side chamber 12 of FIG. 1. Thus the first and second lead-through connections 13, 15 are substrate lead-through connections via which the substrate 1 transported between the side chambers 42, 52 and the deposition chamber 4. The first and second lead-through connections 13, 15 comprise lead-through chamber 18 provided between the side chambers 42, 52 and the deposition chamber 4, and the second lead-through port 17 provided between the side chamber 42, 52 and the lead-through chamber 18, and the first lead-through ports 19 provided between the lead-through chamber 18 and the deposition chamber 4 for forming a lead-through between the side chamber 42, 52 and the deposition chamber 4.

The first side chamber 42 may comprise pre-treating devices 11, 48 for pre-treating the substrate 1 before transporting it to the deposition chamber 4 with the transport mechanism 22, 26, 28, 24 in the direction of arrow S. The transport mechanism of FIG. 2 corresponds the transport mechanism of FIG. 1.

The first reel 22 is in this embodiment provided to the first side chamber 42 and the second reel 24 to the second side chamber 52. The first and second side chamber 42, 52 have side chamber walls 40, 50, respectively, defining process space. The first side chamber 42 comprises one or more pre-treating devices 11, 48 and the second side chamber 52 one or more post-treating devices 56, 58.

The pre-treating devices 48 and post-treating devices 58 may be for example heating device, cooling device, coating device, plasma processing device, tacky roll or any kind of substrate processing device. The plasma processing device may be arranged to provide radicals using plasma discharge.

According to the above, the apparatus may be a process line, the deposition chamber 4 forming a deposition unit in the process line and the process and the side chambers 42, 52 other processing unit. The process line may also comprise further processing unit.

In general the apparatus may be a process line, the deposition chamber 4 forming a deposition unit in the process line and the process and equipment is a process unit or process chamber in the process line arranged before or after the deposition chamber 4.

The embodiment of FIG. 2, the pre-treating device 11 may be heating device and the pre-treating device 48 may be a primer coating device, such as plasma deposition device.

The second side chamber 52 may comprise post-treating devices 58, 56 for post-treating the substrate 1 after transporting it from the deposition chamber 4 with the transport mechanism 22, 26, 28, 24.

In the embodiment of FIG. 2, the post-treating device 56 may be heating device and the post-treating device 48 may be a primer coating device.

The deposition chamber 4 and the substrate support 3 and the nozzle head 5 correspond the embodiment of FIG. 1.

The apparatus comprises a primary pressure device 6 operatively connected to the deposition chamber 4 for controlling the pressure inside the deposition chamber 4, secondary pressure devices 20 operatively connected to the lead-through chambers 18 of the lead-through connections 13, 15, 18 for controlling pressure in the lead-through-chambers 18, and a first and second side chamber pressure devices 46, 54 operatively connected first and second side chamber 42, 52, respectively.

Accordingly, the primary pressure device 6 is arranged to provide a first pressure inside the deposition chamber 4, the secondary pressure devices 20 are arranged to provide a second pressures inside the one or more lead-through chambers 18, and the side chamber pressure devices 46, 54 a third pressure inside the side chambers 42, 52. The first and second pressure are adjusted and controlled relative to each other such that the first pressure inside the deposition chamber 4 is higher than the second pressure inside the one or more lead-through chambers 18 during the operation of the apparatus, as is generally disclosed above. The third pressure may be higher, lower or equal to the second pressure.

FIGS. 1 and 2 disclose roll-to-roll apparatuses in which the substrate 1 is continuously moved from the first reel 22 to the second reel. FIG. 3 shows an embodiment of a batch process and apparatus for batch processing using atomic layer deposition. The apparatus of FIG. 3 corresponds the apparatus of FIG. 1, except that the side chamber 12 is replaced by a loading chamber 112 having loading chamber walls 110. The loading chamber 112 may be loading and unloading chamber for loading and unloading substrates 101 to and from the deposition chamber 4.

The apparatus further comprises the lead-through connection 16 provided between the loading chamber 112 and the deposition chamber 4. The lead-through connection 16 having the lead-through chamber 18 provided between the loading chamber 112 and the deposition chamber 4, and the second lead-through port 17 provided between the loading chamber 112 and the lead-through chamber 18, and the first lead-through port 19 provided between the lead-through chamber 18 and the deposition chamber 4 for forming a lead-through between the loading chamber 112 and the deposition chamber 4.

The loading chamber 112 comprises loading device 120 having the loading member 122. The loading member may be loading arm, loading support or robot arm, or the like. The loading device 120, 122 is arranged to load and unload substrates 101 into the deposition chamber 4. The deposition chamber 4 may comprise a substrate support 124 for supporting one or more substrates 101 in the deposition chamber 4. The substrate support 124 may be plane, rack or the like.

The loading device 120, 122 is arranged to load and unload the substrates 101 into and from the deposition chamber via the lead-through connection 16, and through the lead-through ports 17, 19 and the lead-through chamber 18. Thus the lead-through connection 16 between the loading chamber 112 and the deposition chamber 4 is substrate lead-through connection.

The apparatus further comprises another process equipment 34 connected to the deposition chamber. The process equipment 34 may also be a gas manifold arranged to supply precursor gases inside the deposition chamber 4 and to exhaust process gas or gases from the deposition chamber 4. It should be noted that the apparatus may also comprise two or more process equipments 34 implemented as gas sources, gas discharges or gas manifolds.

The gas source 34 is arranged to supply precursor gases to the deposition chamber in order to process or coat the substrate 101 by subjecting the surface of the substrate to at least first and second precursor according to the principles of atomic layer deposition, the atomic layer deposition being carried out as batch process in the deposition chamber 4.

According to the present invention, the primary pressure device 6 is arranged to provide a first pressure inside the deposition chamber 4, the secondary pressure devices 20 are arranged to provide a second pressures inside the lead-through chambers 18, and the side chamber pressure devices 114, operatively connected to the loading chamber 114, a third pressure inside the loading chamber 114. The first and second pressure are adjusted and controlled relative to each other such that the first pressure inside the deposition chamber 4 is higher than the second pressure inside the one or more lead-through chambers 18 during the operation of the apparatus, as is generally disclosed above. The third pressure may be higher, lower or equal to the second pressure.

The apparatus according to the present invention, any embodiment of the present invention, is operated by controlling the second pressure inside the one or more lead through chambers 18 during the operation of the apparatus using the secondary pressure device 20. The operation of the apparatus may also comprise controlling the first pressure inside the deposition chamber 4 during the operation of the apparatus using the primary pressure device 6.

The operation of the device is carried out by adjusting the first and second pressure relative to each other such that the first pressure inside the deposition chamber 4 is higher than the second pressure inside the one or more lead-through chambers 18 during the operation of the apparatus.

The adjustment is carried out by controlling the primary and secondary pressure devices 6, 20 independently of each other such that the first pressure inside the deposition chamber 4 is higher than the second pressure inside the one or more lead-through chambers 18, or adjusting the second pressure with the secondary pressure device 20 based on the control or adjustment of the primary pressure device 6 or first pressure inside the deposition chamber 4, or adjusting the first pressure with the primary pressure device 6 based on the control or adjustment of the secondary pressure device 20 or second pressure inside the lead-through chamber 18.

In all embodiments of the apparatus and in all the operation modes of the apparatus, the third pressure inside the process chamber 12, 42, 52, 112 may be controlled during the operation of the apparatus using the side chamber pressure device 14, 46, 54, 114 such the third pressure is higher, lower or equal to the second pressure.

Furthermore, the apparatus may be operated by adjusting the first, second and third pressure relative to each other such that the third pressure corresponds substantially normal air pressure (NTP) or is substantially 1 bar, the second pressure being lower than the third pressure and the first pressure being higher than the second pressure, or the first, second and third are vacuum pressures under 1 bar.

It will be obvious to a person skilled in the art that, as the technology advances, the inventive concept can be implemented in various ways. The invention and its embodiments are not limited to the examples described above but may vary within the scope of the claims.

1.-17. (canceled)

18. An apparatus for processing a surface of a web-like substrate, the apparatus comprising:
a deposition chamber inside which the surface of the substrate is processed by subjecting the surface of the substrate web-like to successive surface reactions of at least a first precursor and a second precursor according to principles of atomic layer deposition, the deposition chamber having deposition chamber walls;
one or more side chambers connected to the deposition chamber; and
one or more lead-through connections provided between the one or more side chambers and the deposition chamber and arranged to form one or more lead-throughs from the one or more side chambers to inside the deposition chamber for transporting the web-like substrate between the one or more side chambers and the deposition chamber;
wherein the one or more lead-through connections comprises:
one or more lead-through chambers provided between the one or more side chambers and the deposition chamber;
one or more first lead-through ports provided between the one or more lead-through chambers and the deposition chamber;
one or more second first lead-through ports provided between the one or more side chambers and between the one or more lead-through chambers; and
a secondary pressure device operatively connected to the one or more lead-through chambers for controlling pressure in the lead-through-chamber,
the apparatus further comprising:
a transport mechanism arranged to transport the web-like substrate between the one or more side chambers and the deposition chamber through the one or more lead-through chambers; and
a primary pressure device operatively connected to the deposition chamber for controlling the pressure inside the deposition chamber, the primary pressure device arranged to provide a first pressure inside the deposition chamber and the secondary pressure device is arranged to provide a second pressure inside the one or more lead-through chambers, the second pressure being lower than the first pressure.

19. The apparatus according to claim 18, wherein the primary pressure device and the secondary pressure device are independently controllable.

20. The apparatus according to claim 18, wherein the side chamber is provided with a side chamber pressure device for controlling the pressure inside of the side chamber.

21. The apparatus according to claim 18, wherein the side chamber is a loading chamber for loading the web-like substrate to the deposition chamber, and the lead-through connection is a substrate lead-through connection via which the web-like substrate transported between the loading chamber and the deposition chamber; or
the side chamber is a process chamber inside which the substrate is processed, and the lead-through connection is a substrate lead-through connection via which the web-like substrate transported between the process chamber and the deposition chamber; or
the apparatus is a process line, the deposition chamber forming a deposition unit in the process line and the side chamber is a process unit or process chamber in the process line arranged before or after the deposition chamber.

22. The apparatus according to claim 21, wherein the apparatus comprises:
the side chamber or the loading chamber and a transport mechanism arranged to transport the web-like substrate from the side chamber or the loading chamber to the deposition chamber and from the deposition chamber to the side chamber or the loading chamber via the substrate lead-through connection; or
a first side chamber or the loading chamber, a second side chamber or an unloading chamber and the transport mechanism arranged to transport the web-like substrate from the first side chamber or the loading chamber to the deposition chamber via a first substrate lead-through connection and from the deposition chamber to the second side chamber or the unloading chamber via a second substrate lead-through connection.

23. The apparatus according to claim 22, wherein the side chamber comprises one or more pre-treating devices for pre-treating the web-like substrate before transporting the web-like substrate to the deposition chamber; or
the side chamber comprises one or more post-treating devices for post-treating the web-like substrate after transporting the web-like substrate from the deposition chamber; or
the side chamber comprises one or more pre-treating devices for pre-treating the web-like substrate before transporting the web-like substrate to the deposition chamber and one or more post-treating devices for post-treating the web-like substrate after transporting the web-like substrate from the deposition chamber.

24. The apparatus according to claim 18, wherein the primary pressure device and the secondary pressure device are arranged to control the first pressure and the second pressure such that the first pressure is higher than the second pressure at all times during the operation of the apparatus.

25. The apparatus according to claim 18, wherein the primary and secondary pressure devices are vacuum pumps; or
the primary and secondary pressure devices are vacuum pumps, the secondary vacuum pump having higher capacity than the first vacuum pump.

26. A method for operating a substrate processing apparatus, the apparatus comprising:
a deposition chamber inside which the surface of the substrate is processed by subjecting the surface of the substrate to successive surface reactions of at least a first precursor and a second precursor according to principles of atomic layer deposition, the deposition chamber having deposition chamber walls;
one or more side chambers connected to the deposition chamber; and
one or more lead-through connections provided be-tween the one or more side chambers and the deposition chamber and arranged to form one or more lead-throughs from the one or more side chambers to inside the deposition chamber for transporting the substrate between the one or more side chambers and the deposition chamber,
a primary pressure device operatively connected to the deposition chamber for providing a first pressure inside the deposition chamber, the one or more lead through connections comprising: one or more lead-through chambers provided between the one or more side chambers and the deposition chamber; and
a secondary pressure device operatively connected to the one or more lead-through chambers for providing a second pressure inside the one or more lead-through chambers, wherein the method comprises:
controlling the first pressure inside the deposition chamber during the operation of the apparatus using the primary pressure device,
controlling the second pressure inside the one or more lead through chambers during the operation of the apparatus using the secondary pressure device, and
adjusting the first and second pressure relative to each other such that the first pressure inside the deposition chamber is higher than the second pressure inside the one or more lead-through chambers during the operation of the apparatus.

27. The method according to claim 26, wherein the method comprises adjusting the first and second pressure relative to each other during:
atomic layer deposition process in the deposition chamber, in which the surface of the substrate is subjected to successive surface reactions of the first and second precursors inside the deposition chamber; or
maintenance process of the apparatus or the deposition chamber; or
during changing the first pressure inside the deposition chamber.

28. The method according to claim 26, wherein:
controlling the primary and secondary pressure devices independently of each other such that the first pressure inside the deposition chamber is higher than the second pressure inside the one or more lead-through chambers; or
adjusting the second pressure with the secondary pressure device based on the control or adjustment of the primary pressure device or first pressure inside the deposition chamber;
adjusting the first pressure with the primary pressure device based on the control or adjustment of the secondary pressure device or second pressure inside the lead-through chamber.

29. The method according to claim 26, wherein the side chamber comprises a side chamber pressure device for providing a third pressure inside the side chamber, the method comprising controlling the third pressure inside the side chamber during the operation of the apparatus using the side chamber pressure device.

30. The method according to claim 29, wherein by adjusting the second and third pressure relative to each other such that:
the third pressure inside the side chamber is higher than the second pressure inside the one or more lead-through chambers during the operation of the apparatus; or
the third pressure inside the side chamber is lower than the second pressure inside the one or more lead-through chambers during the operation of the apparatus; or
the third pressure inside the side chamber is substantially equal to the second pressure inside the one or more lead-through chambers during the operation of the apparatus.

31. The method according to claim 29, wherein by adjusting the first, second and third pressure relative to each other such that:
the third pressure corresponds substantially normal air pressure (NTP) or is substantially 1 bar, the second pressure being lower that the third pressure and the first pressure being higher than the second pressure; or
the first, second and third are vacuum pressures under 1 bar.

32. The method according to claim 29, wherein by adjusting the first, second and third pressure relative to each other such that:
adjusting the first pressure to 12-20 mbar, the second pressure to 6-11 mbar and the third pressure to 1-6 mbar; or
adjusting the first pressure to 101-500 mbar, the second pressure to 1-100 mbar and the third pressure to 501-1100 mbar.

33. The method according to claim 26, wherein the apparatus is an apparatus for processing a surface of a web-like substrate, the apparatus comprising:
a deposition chamber inside which the surface of the substrate is processed by subjecting the surface of the substrate web-like to successive surface reactions of at least a first precursor and a second precursor according to principles of atomic layer deposition, the deposition chamber having deposition chamber walls;
one or more side chambers connected to the deposition chamber; and
one or more lead-through connections provided between the one or more side chambers and the deposition chamber and arranged to form one or more lead-throughs from the one or more side chambers to inside the deposition chamber for transporting the web-like substrate between the one or more side chambers and the deposition chamber;
wherein the one or more lead-through connections comprises:
one or more lead-through chambers provided between the one or more side chambers and the deposition chamber;
one or more first lead-through ports provided between the one or more lead-through chambers and the deposition chamber;
one or more second first lead-through ports provided between the one or more side chambers and between the one or more lead-through chambers; and
a secondary pressure device operatively connected to the one or more lead-through chambers for controlling pressure in the lead-through-chamber,
the apparatus further comprising:
a transport mechanism arranged to transport the web-like substrate between the one or more side chambers and the deposition chamber through the one or more lead-through chambers; and
a primary pressure device operatively connected to the deposition chamber for controlling the pressure inside the deposition chamber, the primary pressure device arranged to provide a first pressure inside the deposition chamber and the secondary pressure device is arranged to provide a second pressure inside the one or more lead-through chambers, the second pressure being lower than the first pressure.
